(19) United States
(12) Patent Application Publication
(10) Pub. No.: US 2026/0107402 A1
(43) Pub. Date: Apr. 16, 2026

(54) INVERTER, METHOD FOR MANUFACTURING AN INVERTER, AND ELECTRIC MACHINE

(71) Applicant: Schaeffler Technologies AG & Co. KG, Herzogenaurach (DE)

(72) Inventors: Dr.-Ing. Bao Ngoc An, Karlsruhe (DE); Momo Lažetic, Žilina (SK); Andreas Humbert, Ottersweier (DE)

(73) Assignee: Schaeffler Technologies AG & Co. KG, Herzogenaurach (DE)

(21) Appl. No.: 19/113,741

(22) PCT Filed: Sep. 8, 2023
(86) PCT No.: PCT/DE2023/100585

§ 371 Date: Mar. 20, 2025

(30) Foreign Application Priority Data
Sep. 21, 2022 (DE) 102022124175.0

(51) Int. Cl. H05K 7/14

(52) U.S. Cl. CPC H05K 7/14329

(57) ABSTRACT

The invention relates to an inverter (1) for supplying current to an electric machine (20), in particular an electric machine (20) within a drive train (3) of a fully electric or hybrid motor vehicle (4), said inverter comprising: an inverter housing (2) inside which the power electronics (5) of the inverter (1) are accommodated; an electrical input (6) for coupling to an electrical DC voltage source (7); and an electrical output (8) for coupling to an electrical AC voltage consumer (9), the power electronics (5) being designed to transform the DC voltage applied to the electrical input (6) into an AC voltage applied to the electrical output (8), the inverter (1) also comprising a passive EMC filter (10) and/or an active EMC filter (11), the active EMC filter (11) being positioned on a flexible printed circuit board (12) which is fixed on a laminated busbar (13).

### CROSS-REFERENCE TO RELATED APPLICATIONS

This application is a U.S. national stage application under 35 U.S.C. § 371 that claims the benefit of priority under 35 U.S.C. § 365 of International Patent Application No. PCT/DE2023/100585, filed on Aug. 9, 2023, designating the United States of America, which in turn claims the benefit of priority under 35 U.S.C. §§ 119,365 of German Patent Application No. 102022124175.0, filed on Sep. 21, 2022, the contents of which are relied upon and incorporated herein by reference in their entirety.

### FIELD OF THE DISCLOSURE

The present disclosure relates to an inverter for supplying current to an electric machine, such as an electric machine within a drive train of a fully electric or hybrid motor vehicle, said inverter comprising an inverter housing inside which the power electronics of the inverter are accommodated, an electrical input for coupling to an electrical DC voltage source and an electrical output for coupling to an electrical AC voltage consumer, wherein the power electronics are designed to transform the DC voltage applied to the electrical input into an AC voltage applied to the electrical output, wherein the inverter also comprises a passive EMC filter and/or an active EMC filter. The disclosure also relates to a method for manufacturing an inverter and to an electric machine.

### BACKGROUND OF THE DISCLOSURE

Electric motors are increasingly being used to drive motor vehicles to create alternatives to internal combustion engines that require fossil fuels.

### SUMMARY OF THE DISCLOSURE

It is an object of the disclosure to provide an inverter for supplying current to an electric machine, such as an electric machine within a drive train of a fully electric or hybrid motor vehicle, which can meet high EMC requirements while being inexpensive to manufacture and easy to install. It is furthermore an object of the disclosure to implement a method for manufacturing an inverter and an electric machine.

The present disclosure includes an inverter for supplying current to an electric machine, said inverter comprising an inverter housing inside which the power electronics of the inverter are accommodated, an electrical input for coupling to an electrical DC voltage source and an electrical output for coupling to an electrical AC voltage consumer, wherein the power electronics are designed to transform the DC voltage applied to the electrical input into an AC voltage applied to the electrical output, wherein the inverter also comprises a passive EMC filter and/or an active EMC filter, wherein the active EMC filter is arranged on a flexible printed circuit board which is fixed on a laminated busbar.

This has the advantage that an active and a passive EMC filter can form a hybrid filter. The active EMC filter may be configured to, for example, filter frequency ranges up to 2 MHz, while the passive EMC filter may be configured to filter, for example, frequency ranges higher than 2 MHz. This may allow for a noticeable reduction in size, for example of the core material of the passive EMC filter, which in turn leads directly to a reduction in installation space and manufacturing costs.

Optimal cooling of the active and passive EMC filter can also be provided via the inverter housing.

Finally, the inverter also allows for a significant reduction in installation effort, which will be discussed in more detail later.

The power electronics of the inverter are accommodated in an inverter housing. The inverter housing can preferably be formed from a metallic material, particularly preferably from aluminum, gray cast iron or cast steel, in particular by means of a primary shaping process such as casting or die-casting. The inverter housing can have a pot-like spatial shape. The housing cover can be inserted into the pot-like inverter housing. In some embodiments, the housing cover to rest on the pot-like inverter housing and cover its opening.

The inverter housing can also be part of the motor housing of an electric machine or vice versa. This means that the inverter housing is formed to be completely or partially integral, in particular monolithic, with the motor housing.

According to a further embodiment of the disclosure, the housing cover can be formed from a metallic material, in particular from a steel. The inverter housing can be formed from a metallic material, such that good electromagnetic shielding of the surrounding components can be achieved with a metal inverter housing and/or housing cover. The housing cover can be formed from pure sheet metal.

The power electronics received in the inverter housing can be provided for an electric machine of an electrically operable drive train of a motor vehicle. The power electronics can be a combination of different components that control or regulate a current to the electric machine of the axle drive train, including the peripheral components required for this purpose, such as cooling elements or power supply units. The power electronics can contain one or more power electronics components that are configured to control or regulate a current. These can be one or more power switches, such as power transistors. The power electronics can have more than two phases or current paths which are separate from one another and which each have at least one separate power electronics component. The power electronics can be designed to control or regulate a power per phase with a peak power, such as continuous power, of at least 10 W, in some embodiments at least 100 W, and in some embodiments at least 1000 W.

The power electronics can also have a control unit, for example in the form of control electronics and/or sensor electronics, for the electrical axle drive train.

According to an embodiment of the disclosure, the laminated busbar can be thermally connected to the inverter housing with the interposition of a thermal coupling layer. The advantage of this embodiment is that it allows for particularly good cooling of the active EMC filter. The thermal coupling layer has thermal conductivity for this purpose.

According to an embodiment of the disclosure, the passive EMC filter can comprise a magnet element that surrounds the laminated busbar at least in sections and/or completely. This means that the filter effect of the corresponding passive EMC filter can be designed in an advantageous manner.

Furthermore, according an embodiment of the disclosure, the magnet element can be connected to the inverter housing in a materially bonded manner, which is advantageous from an installation point of view.

According to an embodiment of the disclosure, the passive EMC filter can comprise a capacitor.

Furthermore, the capacitor can be arranged on the flexible printed circuit board. The advantage of this design is that the capacitor of the passive EMC filter can be arranged on the printed circuit board in an installation-friendly and production-optimized manner. In principle, it would also be conceivable to arrange the capacitor on a busbar.

In another embodiment of the disclosure, the flexible printed circuit board can be fixed to the laminated busbar in a materially bonded manner. This allows for a high quality planar fixation of the printed circuit board to be achieved. The material bond can be produced, for example, by gluing or welding (e.g., resistance welding).

An object of the disclosure is further achieved by a method for manufacturing an inverter for supplying current to an electric machine, comprising the following steps:
providing an inverter housing within which the power electronics of the inverter are accommodated,
fixing a flexible printed circuit board on a laminated busbar,
equipping the flexible printed circuit board with an active EMC filter,
mounting the laminated busbar with the active EMC filter fixed to it in the inverter housing.

According to an embodiment of the disclosure, a capacitor can be arranged as a component of a passive EMC filter on the flexible printed circuit board.

An electrically operable axle drive train comprises an electric machine and preferably a transmission arrangement coupled to the electric machine. The transmission arrangement and the electric machine form a structural unit. This can be formed, for example, by means of a drive train housing, in which the transmission arrangement and the electric machine are accommodated together.

A motor housing can enclose the electric machine. A motor housing can also accommodate the control and power electronics. The motor housing can furthermore be part of a cooling system for the electric machine and can be designed such that cooling fluid can be supplied to the electric machine via the motor housing and/or the heat can be dissipated to the outside via the housing surfaces. In addition, the motor housing protects the electric machine and any electronics that may be present from external influences.

A motor housing can be formed from a metallic material. Advantageously, the motor housing can be formed from a metallic cast material, such as die-cast aluminum, die-cast magnesium, gray cast iron, or cast steel.

The electric machine can be dimensioned such that vehicle speeds of more than 50 km/h, more than 80 km/h, and/or more than 100 km/h can be achieved. The electric motor can have an output of more than 30 kW, more than 50 kW, and/or more than 70 kW. Furthermore, the electric machine can provide speeds greater than 5000 rpm, greater than 10,000 rpm, and/or greater than 12,500 rpm.

The electric axle drive train can be operated by means of the power electronics module, in that the power electronics module conducts current into the electrically operable axle drive train, e.g., to a stator winding of the electric machine.

### BRIEF DESCRIPTION OF THE DRAWINGS

The disclosure is explained in more detail below with reference to the drawings without limiting the general concept of the disclosure.

In the drawings:

FIG. 1 shows a motor vehicle with an electric machine in a schematic block diagram,

FIG. 2 shows an inverter for supplying current to an electric machine in a schematic block diagram,

FIG. 3 shows an inverter in a longitudinal sectional view, and

FIG. 4 shows three different mounting states of a passive and active EMC filter in an inverter, each in a longitudinal sectional view.

### DETAILED DESCRIPTION

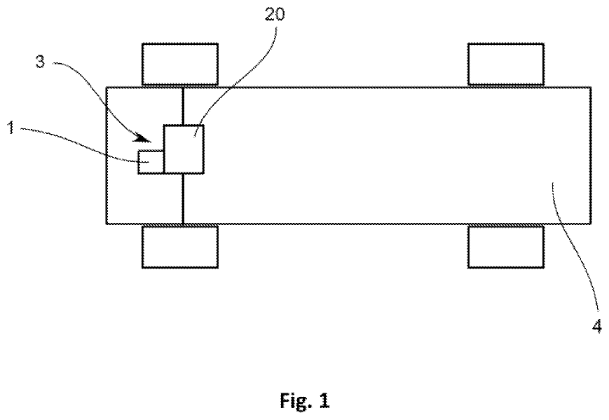

FIG. 1 shows an inverter 1 for supplying current to an electric machine 20 within a drive train 3 of a fully electric or hybrid motor vehicle 4.

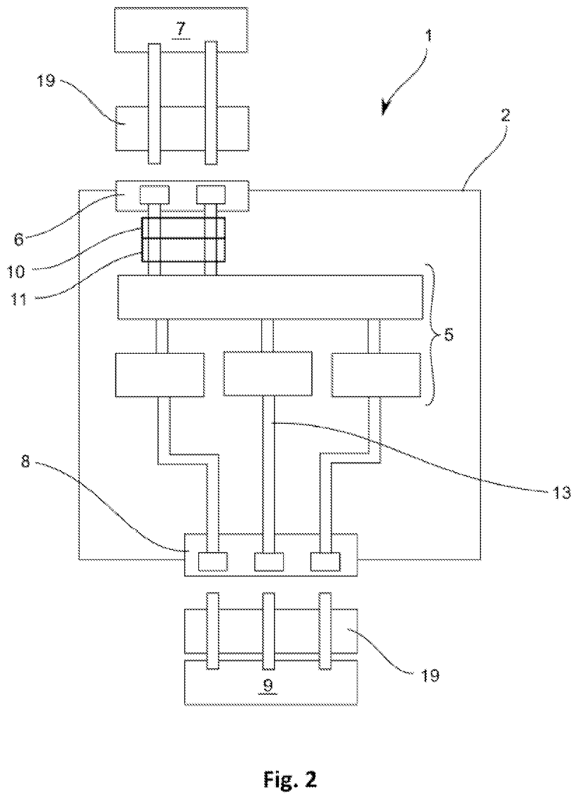

As can be seen from FIG. 2, the inverter 1 comprises an inverter housing 2 inside which the power electronics 5 of the inverter 1 are accommodated, an electrical input 6 for coupling to an electrical DC voltage source 7 and an electrical output 8 for coupling to an electrical AC voltage consumer 9, such as the electric machine 20 in the drive train 3 of the motor vehicle 4. For example, the plug connectors 19 indicated in FIG. 1 can be used to make the respective electrical connections.

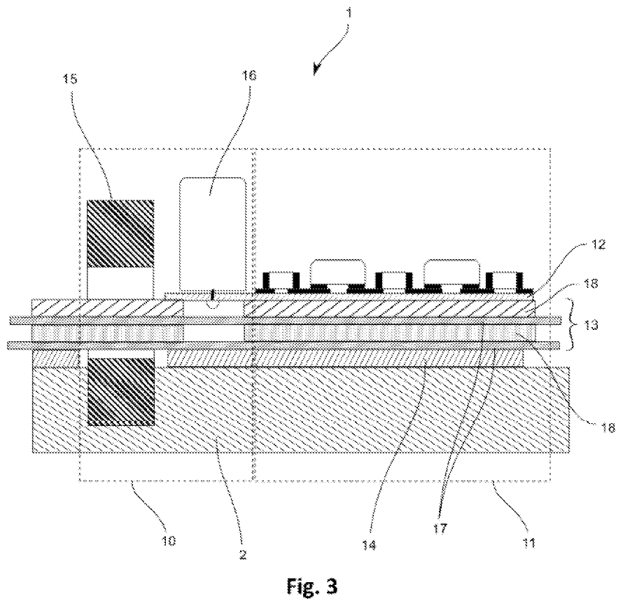

The power electronics 5 are configured to transform the DC voltage applied to the electrical input 6 into an AC voltage applied to the electrical output 8. In order to improve the EMC behavior of the inverter 1, it has a passive EMC filter 10 and an active EMC filter 11. The active EMC filter 11 is arranged on a flexible printed circuit board 12, which is fixed to a laminated busbar 13, which can be understood from the sectional view in FIG. 3.

The laminated busbar 13 is thermally connected to the inverter housing 2 by means of a thermal coupling layer 14 such that heat can be dissipated from the busbar 13 into the inverter housing 2. Furthermore, the busbar 13 is surrounded by laminate layers 18, which electrically insulate the busbar 13 from other components. In the example shown, the busbar 13 has two electrical conductors 17 extending in parallel. It is also possible that instead of the two electrical conductors 17 of a busbar 13, two different busbars 13 are arranged between the laminate layers 18.

The passive EMC filter 10 comprises a ring-shaped magnet element 15 that surrounds the laminated busbar 13 at least in sections in the longitudinal extension, but completely in the circumferential direction. The magnet element 15 is connected to the inverter housing 2 in a materially bonded manner, for example via an adhesive. The passive EMC filter 10 furthermore has a capacitor 16, which is arranged on the flexible printed circuit board 12. In turn, the flexible printed circuit board 12 is fixed in a materially bonded manner to the laminated busbar 13.

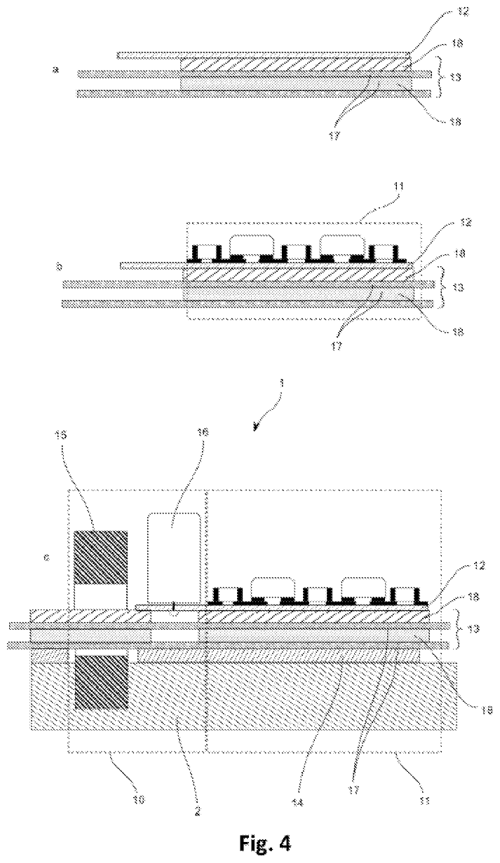

A possible method for manufacturing an inverter 1 for supplying current to an electric machine 20, as illustrated in FIGS. 1-3, is explained in more detail below with reference to the illustrations in FIG. 4.

First, an inverter housing 2 is provided, within which the power electronics 5 of the inverter 1 are accommodated. Then, a fixation of a flexible printed circuit board 12 to a laminated busbar 13 is performed, which is shown in the upper illustration of FIG. 4. The flexible printed circuit board 12 is then equipped with an active EMC filter 11, resulting in the installation state shown in the middle illustration in FIG. 4. In addition, in the embodiment shown, a capacitor 16 is also arranged on the flexible printed circuit board 12 as a component of a passive EMC filter 10. The laminated busbar 13 with the active EMC filter 11 fixed to it is then mounted in the inverter housing 2, as shown in the lower illustration in FIG. 4. First, the ring-shaped magnet element 15 was inserted here into the inverter housing 2 and fixed in place, and then the equipped busbar 13 was guided through the ring-shaped magnet element 15.

The disclosure is not limited to the embodiments shown in the figures. The above description is therefore not to be regarded as limiting, but rather as illustrative. The following claims are to be understood as meaning that a stated feature is present in at least one embodiment of the disclosure. This does not exclude the presence of further features. Where the claims and the above description define ‘first’ and ‘second’ features, this designation serves to distinguish between two features of the same type without defining an order of precedence.

### LIST OF REFERENCE SIGNS

1 Inverter
2 Inverter housing
3 Drive train
4 Motor vehicle
5 Power electronics
6 Input
7 DC voltage source
8 Output
9 AC voltage consumer
10 Passive EMC filter
11 Active EMC filter
12 Flexible printed circuit board
13 Laminated busbar
14 Thermal coupling layer
15 Magnet element
16 Capacitor
17 Electrical conductor
18 Laminate layer
19 Plug connector
20 Electric machine

1. An inverter for supplying current to an electric machine, comprising:
an inverter inside which power electronics are accommodated;
an electrical input for coupling to an electrical DC voltage source;
an electrical output for coupling to an electrical AC voltage consumer, wherein the power electronics are designed to transform the DC voltage applied to the electrical input into an AC voltage applied to the electrical output; and
at least one of a passive EMC filter and an active EMC filter arranged on a flexible printed circuit board which is fixed on a laminated busbar.

2. The inverter of claim 1, wherein the laminated busbar is thermally connected to the inverter housing with the interposition of a thermal coupling layer.

3. The inverter of claim 1, wherein the passive EMC filter comprises a magnet element that surrounds the laminated busbar at least in sections.

4. The inverter according to claim 3, wherein the magnet element is connected to the inverter housing in a materially bonded manner.

5. The inverter of claim 1, wherein the passive EMC filter comprises a capacitor.

6. The inverter of claim 5, wherein the capacitor is arranged on the flexible printed circuit board.

7. The inverter of claim 1, wherein the flexible printed circuit board is fixed to the laminated busbar in a materially bonded manner.

8. A method for manufacturing an inverter for supplying current to an electric machine, comprising the steps of:
providing an inverter housing within which the power electronics are accommodated;
fixing a flexible printed circuit board on a laminated busbar;
equipping the flexible printed circuit board with an active EMC filter; and
mounting the laminated busbar with the active EMC filter fixed to it in the inverter housing.

9. The method of claim 8, wherein a capacitor is arranged as a component of a passive EMC filter on the flexible printed circuit board.

10. (canceled)

11. A vehicle comprising:
an electric machine that includes an inverter, the inverter comprising:
an inverter housing having power electronics of the inverter accommodated therein;
an electrical input for coupling to an electrical DC voltage source;
an electrical output for coupling to an electrical AC voltage consumer, wherein the power electronics are configured to transform the DC voltage applied to the electrical input into an AC voltage applied to the electrical output; and
an active EMC filter arranged on a flexible printed circuit board fixed on a laminated busbar.

12. The vehicle of claim 11, wherein the inverter further comprises:
a passive EMC filter.

13. The vehicle of claim 12, wherein the passive EMC filter comprises a magnet element that surrounds the laminated busbar at least in sections.

14. The vehicle of claim 13, wherein the magnet element is connected to the inverter housing in a materially bonded manner.

15. The vehicle of claim 12, wherein the passive EMC filter comprises a capacitor.

16. The vehicle of claim 15, wherein the capacitor is arranged on the flexible printed circuit board.

17. The vehicle of claim 11, wherein the laminated busbar is thermally connected to the inverter housing with the interposition of a thermal coupling layer.

18. The vehicle of claim 11, wherein the flexible printed circuit board is fixed to the laminated busbar in a materially bonded manner.

19. The vehicle of claim 11, wherein said vehicle is an electric vehicle.

20. The vehicle of claim 20, wherein said vehicle is a hybrid electric vehicle.
